(19) United States
(12) Patent Application Publication
(10) Pub. No.: US 2002/0186086 A1
(43) Pub. Date: Dec. 12, 2002

(54) Random number generator

(75) Inventors: Andreas Curiger, Buchs (CH); Stephen N. Grider, Argyle, TX (US)

Correspondence Address: Roger L. Maxwell, Esq., Jenkens & Gilchrist, P.C., 1445 Ross Avenue, Suite 3200, Dallas, TX, 75202-2799, US

(73) Assignee: Dallas Semiconductor Corporation

(21) Appl. No.: 09/879,686

(22) Filed: Jun. 12, 2001

(51) Int. Cl. H03B 29/00; H03K 3/84; G06F 7/58

(52) U.S. Cl. 331/78; 327/164; 708/251; 708/252

(57) ABSTRACT

An improved random number generator for micro-controllers is provided with multiple free running oscillators. These oscillators may be ring oscillators. They run at different frequencies. A phase difference between at least two of the oscillators provides the random number. The determination of a phase difference can be done by sampling the high speed oscillator using the lower speed oscillator. This sampling of the oscillators for the determination of a phase difference can be controlled by an oscillators as well. The random number is picked up from a shift register which provides feedback to a control circuit which can alter the frequency of one or more (including all) of the oscillators so that an increased randomness can be achieved. The random number from the shift register is loaded into a linear feedback shift register (LFSR) to generate independent uniform random data. An additional oscillator such as a third low speed oscillator can be used to frequency modulate one of the other oscillators to increase randomness. This also makes attacks on the random number generator much less possible. Attacking the random number generator by using variations in temperature and/or changes in voltages to the chip are rendered ineffective.

### BACKGROUND OF THE INVENTION

1. Field of the Invention

The present invention relates generally to an improved random number generator for microcontrollers and the method of making and using the same.

2. Description of the Related Art

Secure microcontrollers and, in particular, those type of microcontrollers which are used for the transformation oftext and/or secured financial transactions operate by using and requiring the use of random numbers being created by the microcontroller. Various types of encryption require the controller or the computer to have access to a random number.

Various methodologies for producing random number generators have been known in the art. Items such as time measurement and the like have been used as well as the use of various free-running oscillators and sampling these free-running oscillators at various points. For example Dias U.S. Pat. No. 4,810,975 entitled RANDOM NUMBER GENERATOR USING A SAMPLED OUTPUT OF VARIABLE FREQUENCY OSCILLATOR shows a variable frequency oscillator that is sampled at an oscillating point in time being used. Another sampled analog oscillator arrangement is shown in Dias U.S. Pat. No. 4,855,690 entitled INTEGRATED CIRCUIT RANDOM NUMBER GENERATOR USING SAMPLED OUTPUT OF A VARIABLE FREQUENCY OSCILLATOR. Both of the aforementioned Dias patents are commonly owned with this application. Also the use of a counter connected to zener diodes to count noise has also been employed. However, problems have occurred with respect to these types of devices in that a hacker or nefarious individual can compromise the randomness of the random number generator by altering temperature, timing, voltage or the like. Various attempts have been made to ameliorate this possibility; however, none have been entirely successful as the ingenuity of various attackers on the random number generators have been identified. One of the more common ways to generator a random number generator is to use free-running oscillators such as was used in the Dallas Semiconductor device No. DS-5002. However, as noted above by controlling temperature, voltage or the like the randomness of this type of random number generator which operates by using a simple phase difference between two free-running oscillators such as is used on the DS-5002 may not be random enough. Specifically, even though the oscillators in the DS-5002 might and may change phase relationship based on process variation, temperature or supply voltages, the randomness is not sufficient to guarantee an absolutely random number.

### SUMMARY OF THE INVENTION

The present invention overcomes the shortcoming of using simple free-running oscillators by eliminating the problem where a clock frequency is used to get the two oscillators to repeat a specific phase difference pattern under a given set of parameters which could lead to a repeating pattern in the sequence of random numbers produced by such a generator.

The present invention eliminates this problem by using a rising edge of the medium-speed oscillator clock to store a current logic value of the high-speed oscillator to the shift and compare circuitry and shift in subsequent values. A third low-speed oscillator is used to modify or modulate the medium speed oscillator. After a given number of medium-speed clock cycles, a byte of random number will be available. After a slightly larger number of clock cycles, the next byte of random numbers will be ready. These two available numbers are then compared to each other. If they are identical, another byte of random numbers will be available after yet another group of clock cycles will be compared to the current value. After a given number of matches a signal will be toggled which determines whether the high-speed oscillator should run a normal or modified speed respectively. This modification of speed may be by use of additional delay elements or the like.

Whenever a byte from the shift and compare circuit is ready, it will be loaded in parallel into a large linear feedback shift register ideally of 23 bits in length. The actual random byte available to the user will reside in the lowest 8 bits of this multiple bit linear feedback shift register or (LFSR). This LFSR will shift using the high-speed ring as its clock source during idle time. A shift ideally is stopped during reload as well as during reads. A polynomial is used for a feedback loop. Approximately 356,960 suitable polynomials for a 23-bit shift register are possible. Increasing the size of the shift circuit will obviously increase the number of suited polynomials for the feedback.

By use of the shift and compare circuit and the LFSR, it is possible to remove or ameliorate the possibility of “phase interlocking” caused by changing the temperature and the supply voltage. The compare circuit simply checks the value of the last three random bytes. In the case of equality, it is able to change the frequency of the random sample source in order to avoid a lockout which would be the case ifthe temperature and supply voltage were altered so as to force a repeating pattern in the sequence of numbers.

### BRIEF DESCRIPTION OF THE DRAWINGS

Other advantages and novel features of the present invention can be understood and appreciated by reference to the following detailed description of the invention taken into conjunction with the accompanying drawing in which:

FIG. 1 is a schematic diagram according to one embodiment of this invention.

### DETAILED DESCRIPTION

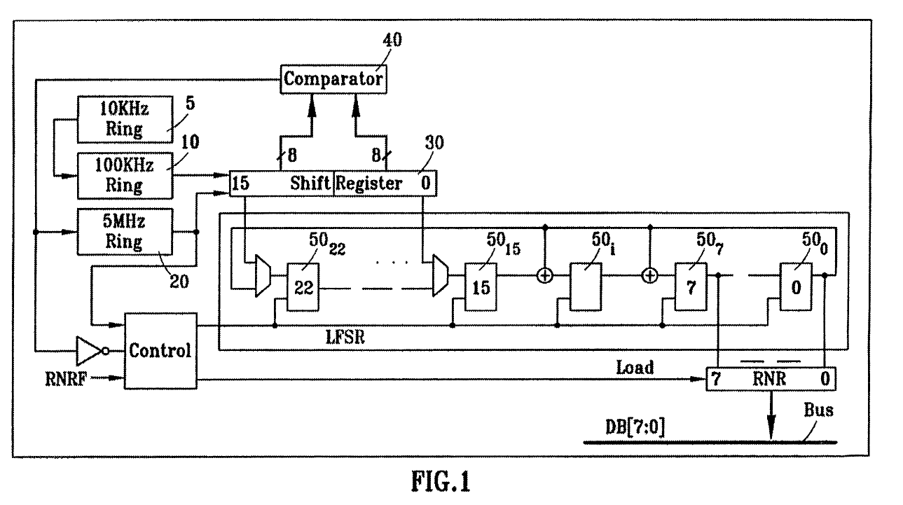

Referring now to FIG. 1, wherein the random number generator according to one embodiment of this invention is shown. Items 5 and 10 and 20 are the low, medium and high-speed free-running oscillators, respectively which are ideally ring oscillators using delay elements to form the ring. In some embodiments oscillators may also have the ability to be modified by changing the number of delay elements in the ring. The phase difference between these two rings actually allows for the calculation of the random number; however, as noted above, the shift register 30 and the comparator 40 and the feedback loop into the high-speed oscillator 20 prevents the phase interlocking discussed above. A linear feedback shift register formed of the gates 50₀ through 50₂₂ stores, for example, the lowest eight bits available to the user in the RNR register bits 0-7. It should be noted at this point that the random number generator is constantly updating into the LFSR regardless of whether a number has been read or not from the RNR register. The LFSR will continue to shift during the time when no load and no read occurs. The pattern in the 23-bit linear feedback register will not repeat until after approximately 8 million clock cycles if no random data is input. Given the normal clock cycle of a representative device, this would be approximately 1.68 seconds. However, during this time, as more than 10,000 bytes of additional random number bytes would also have been fed into this LFSR, the chances of having an absolute repeating sequence becomes essentially nil. This has been proven experimentally. Accordingly, by use of this additional linear feedback shift register which constantly alters and provides a feedback into the shift registers which are used to run the free-running oscillators 10 and 20, the device can virtually guarantee that all numbers produced at the RNR register are in fact random and that no given sequence can be predicted.

Obviously, numerous modifications and variations are possible in view of the teaching above. For example, the number of bits in the LFSR may be altered. As one possibility the number of bits used for the RNR register may be different so as to have a higher number of maximum bits generated by the random number or multiple reads for the RNR can be used or a random read of the RNR can generate an additional loop of the amount of time before another read has occurred or the like to increase the randomness of the device. Further, the number of bits used for the RNR register may be different so as to have a higher number of maximum bits generated by the random number or multiple reads for the RNR can be used or a random read of the RNR can generate an additional loop of the amount of time before another read has occurred or the like to increase the randomness of the device.

Accordingly, the present invention is not limited by the specific embodiment disclosed but is capable of numerous rearrangements, modifications or substitutions without departing from the spirit and scope of the invention as set forth and defined by the following claims:

What is claimed is:

1. An improved random number generator apparatus comprising:
a first free running oscillator operating at first frequency;
a second free running oscillator running at a second frequency different from the frequency at which said first free running oscillator operates;
a means to detect a phase difference between said first and second oscillators;
a linear feedback shift register coupled to said first and second free running oscillator; and
a means to alter the frequency of operation of at least the first free running oscillator.

2. An apparatus as in claim 1 further comprising:
a third free running oscillator coupled to said second free running oscillator for frequency modulating the output from said oscillator.

3. An apparatus as in claim 2 further comprising:
a comparator coupled to means to detect a phase difference and to said means to alter the frequency of operation of the first free running oscillator.

4. An apparatus as in claim 1 wherein said means to detect a phase difference comprises:
a means for sampling controlled by said first free running oscillator.
